(19) United States
(12) Patent Application Publication
(10) Pub. No.: US 2021/0126659 A1
(43) Pub. Date: Apr. 29, 2021

(54) APPARATUS AND METHOD FOR PROCESSING MULTI-USER TRANSMISSIONS TO DISCARD SIGNALS OR DATA CARRYING INTERFERENCE

(71) Applicant: Cloud Network Technology Singapore Pte. Ltd., Singapore (SG)

(72) Inventors: Shin-Lin Shieh, New Taipei (TW); RUI-YU WANG, Taichung City (TW)

(21) Appl. No.: 16/662,232

(22) Filed: Oct. 24, 2019

(51) Int. Cl. H03M 13/00; H03M 13/11; H04W 72/04; H04W 72/08

(52) U.S. Cl. CPC H03M 13/616; H04W 72/082; H04W 72/0466; H03M 13/1102

(57) ABSTRACT

A method for processing signals or data liable to interference arising from the sharing of channels in multi-user transmissions is applied to a base station apparatus. The base station apparatus receives a codeword from a terminal apparatus, and decodes the received codeword using a parity check matrix. The base station apparatus 110 can determine whether interference exists in a signal or data by analyzing the received codeword, and terminates a decoding of the received codeword if interference is found.

### BACKGROUND

The fifth-generation (5G) mobile communication system is being developed. The applications supported by 5G are known for their flexibility and support for multiple application scenarios. The two major services are enhanced mobile broadband (eMBB) and ultra-reliable low-latency communication (URLLC). The eMBB service focuses on an improvement of spectral efficiency for high transmission rates, with transmission rates of 20 gigabits per second (Gbps) and 10 Gbps, on the downlink and uplink respectively. The URLLC service has strict limits on latency (up to 1 millisecond), gives reliability with a success probability of 99.999%, and has sporadic and stochastic features.

Due to the different requirements, multiplexing between the two services is considered. When a terminal apparatus performs URLLC transmissions, in order to ensure its low latency, the terminal apparatus may occupy some resources allocated by other terminal apparatuses performing eMBB transmission. Superposition transmissions will cause serious interference for eMBB signal since the power of URLLC signal is usually greater than that of eMBB, this is problematic.

### BRIEF DESCRIPTION OF THE DRAWINGS

Implementations of the present technology will now be described, by way of embodiment, with reference to the attached figures, wherein:

FIG. 1 is a schematic diagram of one embodiment of a wireless communication system.

FIG. 2 is a flow chart of one embodiment of a method for processing and eliminating interference by the base station apparatus of FIG. 1.

FIG. 3 is a block diagram of one embodiment of the base station apparatus of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

References to “an” or “one” embodiment in this disclosure are not necessarily to the same embodiment, and such references mean “at least one”.

In general, the word “module” as used hereinafter, refers to logic embodied in computing or firmware, or to a collection of software instructions, written in a programming language, such as, Java, C, or assembly. One or more software instructions in the modules may be embedded in firmware, such as in an erasable programmable read only memory (EPROM). The modules described herein may be implemented as either software and/or computing modules and may be stored in any type of non-transitory computer-readable medium or other storage device. Some non-limiting examples of non-transitory computer-readable media include CDs, DVDs, BLU-RAY, flash memory, and hard disk drives. The term “comprising”, when utilized, means “including, but not necessarily limited to”; it specifically indicates open-ended inclusion or membership in a so-described combination, group, series, and the like.

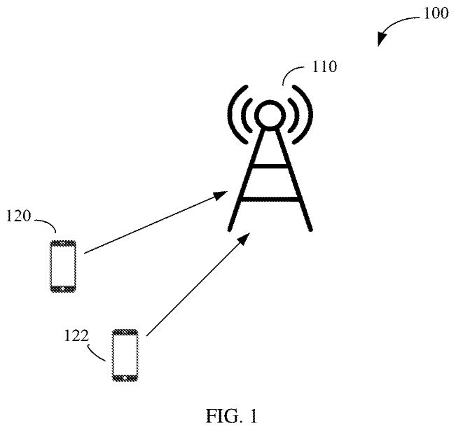

FIG. 1 illustrates a wireless communication system 100 according to an embodiment. The wireless communication system 100 comprises a base station apparatus 110 and two terminal apparatuses. 120 and 122.

The base station apparatus 110 may be a node B (NB) in the universal mobile telecommunication system (UMTS), in the LTE-A, a radio network controller (RNC) in the UMTS, a base station controller (BSC) in the global system for mobile communication (GSM)/GSM edge radio access network (GERAN), and ng-eNB in an evolved universal terrestrial radio access (E-UTRA) base station in connection with the 5G core network (5GC). The apparatus 110 may also be a next generation node B (gNB) in the 5G access network (5G-AN), a remote radio head (RRH), a transmission and reception point (TRP), a cell, and any other apparatus capable of configuring radio communication and managing radio resources within a cell. The base station apparatus 110 may serve one or more terminal apparatuses through a radio interface in the wireless communication system 100.

Each of the terminal apparatuses 120 and 122 may be a mobile station, a mobile device, or a user communication radio terminal apparatus. For example, each may be a portable radio apparatus, which comprises, but is not limited to, a mobile phone, a tablet, a wearable device, a sensor, a personal digital assistant (PDA) with wireless communication capability, and other wireless terminal apparatus equipped with an LTE access module or a 5G NR access module.

In the embodiment, the interface in the wireless communication system 100 utilizes one or more multiplexing and multiple access algorithms to enable simultaneous communications between the base station apparatus 110 and both apparatuses 120 and 122. For example, the wireless communication system 100 may provide multiple access for uplink (UL) transmissions for the terminal apparatus 120/122 to the base station apparatus 110. In the uplink direction, multiplexing suffers from inter-user interference problems, for example, the terminal apparatus 122 may transmit urgent traffic while the terminal apparatus 120 is transmitting scheduled traffic. To allow urgent traffic, a mechanism of power control by power boosting of sporadic urgent traffic is under consideration in 5G communication systems. In one embodiment, the traffic of a latency-critical application is transmitted in a grant-free transmission manner. The features of grant-free transmission are that when the data of the terminal apparatus 122 arrives, it is transmitted immediately in the next available slot, without waiting for scheduling by the base station apparatus 110. If the terminal apparatus 120 and 122 transmit data in different slots, there is no interference between the terminal apparatus 120 and 122, and their respective transmitted data can be correctly detected and decoded. But if the terminal apparatus 120 and 122 transmit data in the same slot, interference may occur between their respective uplink data. However, real urgent traffic transmission is sporadic and unpredictable in any event.

In view of the forgoing, following embodiments describe a method for detecting occurrence of interference.

Taking an uplink transmission scenario where the base station apparatus 110 serves two terminal apparatuses 120 and 122 in a serving cell, FIG. 1 shows an example. The data traffic ‘traffic 1’ is transmitted by the terminal apparatus 120, and the data traffic ‘traffic 2’ is transmitted by the terminal apparatus 122, and a transmission power boosting is considered for ‘traffic 2’. This causes partially overlapped interference to ‘traffic 1’ transmission. In this scenario, the base station apparatus 110 needs to decode ‘traffic 1’, which is partially overlapped by ‘traffic 2’.

In one operating example, the terminal apparatus 120/122 encode information using a low-density parity check (LDPC) code algorithm to generate an LDPC coded signal and transmit the LDPC encoded signal to the base station apparatus 110. Then the base station apparatus 110 receives the LDPC coded signal (codeword bits) from the terminal apparatus 120/122 and decodes the LDPC coded signal using a parity check matrix. In one embodiment, for an additive white Gaussian noise (AWGN) channel, codeword bits received by the base station apparatus 110 can be modeled as two binary hypothesis equations H₀ and H₁, in which a codeword-bits-without-interference H₀ is tested against a codeword-bits-with-interference H₁.

H₀: y=x+z

H₁: y=x+z+I

The H₁ denotes the codeword bits with partially overlapped interference, where x, z, I denote the transmitted signal with amplitude a, the AWGN noise with variance σ², and the interference with amplitude A, respectively.

In the embodiment, assume the unit of overlapped interference codeword is circularly buffered block-by-block, i.e. the number of bits of an interfered-with codeword is equal to a sub-block size of the circular buffer, and the base station apparatus 110 is informed about the number of ‘traffic 2’ pre-configured blocks in advance. Furthermore, suppose a number of column blocks in the parity check matrix is denoted as N, the pre-configured resource of ‘traffic 2’ in k-th sub-block of ‘traffic 1’ codeword, where k≤N and the bit size is denoted by Z, then the codeword bits of the sub-block can be modeled to the binary hypothesis equations as in the following manner.

H₀: yᵢ^{a}=xᵢ^{a}+zᵢ^{a}

H₁: yᵢ^{a}=xᵢ^{a}+zᵢ^{a}+A×xᵢ²; wherein k×Z≤i≤(k+1)×Z.

The other codeword sub-blocks of ‘traffic 1’ not affected by partial interference of ‘traffic 2’, are subjected to H₀.

For overlapped part of ‘traffic 1’, the bit error probabilities for the two hypotheses can be easily derived as P₀(σ²) and P₁(σ², A):

$${P}_{e} ( {H}_{0} ) = {P}_{0} ( {σ}^{2} ) = Q ( \frac{1}{σ} )$$

$${P}_{e} ( {H}_{1} ) = {P}_{1} ( {σ}^{2} , A ) = \frac{1}{2} ( 1 - Q ( ( A - 1 ) \times ( \frac{1}{σ} ) ) ) + \frac{1}{2} ( ( 1 + A ) \times Q ( \frac{1}{σ} ) )$$

In one embodiment, the base station apparatus 110 can detect the occurrence of interference in sub-block resource where there is pre-configuration by the terminal apparatus 122 in the above example. If overlapped interference exists in the pre-configured resource, in one embodiment, the base station apparatus 110 can remove the interfered corresponding codeword bits before decoding the received signal.

In one embodiment, ‘n’ denotes a number of partially overlapped resource blocks and ‘w’ denotes a weight of a parity check equation. The base station apparatus 110 can analyze a theoretical number of initial unsatisfied parity-check equations with and without partial interference for a row block of QC-LDPC decoding scheme. For example, a parity check equation based on an exclusive-OR (XOR) of bis b1, b2, and b3 of a codeword may be represented as “b1 XOR b2 XOR b3=0”. Interference in the shared channel can cause errors in the transmission of binary digits. Let R1, R2, and R3 be the received bits of a codeword that corresponding to b1, b2, and b3 respectively. The computing result of the parity check equation “R1 XOR R2 XOR R3” which is not equal to “0” is referred to as a “unsatisfied” parity check equation. If there is no partially overlapped interference in a shared channel, the theoretical error rate of parity check equation can be formulated as follows (“Equation 1”):

$$\frac{{N}_{0} ( {H}_{0} )}{Z} = {P}_{NoInt} ( w , {P}_{0} ) = {\sum }_{k = 0}^{⌊ k \leq \frac{w - 1}{2} ⌋} {c}_{2 k + 1}^{w} \times {P}_{0}^{2 k + 1} \times {( 1 - {P}_{0} )}^{w - 2 k - 1}$$

where Z is sub-block size of LDPC coding and the No represents that the parity check equation is not satisfied.

On the other hand, if there is partially overlapped interference in the shared channel, the theoretical error rate of parity check equation can be formulated as follows (“Equation 2”):

$$\frac{{N}_{1} ( {H}_{0} , {H}_{1} )}{Z} = {P}_{Int} ( w , {P}_{0} , {P}_{1} ) = {\sum }_{k = 0}^{⌊ k \leq \frac{w - 1}{2} ⌋} {\sum }_{a = 0}^{2 k + 1} {c}_{a}^{w - n} \times {P}_{1}^{a} \times {( 1 - {P}_{1} )}^{w - n - a} \times {P}_{2}^{2 k + 1 - a} \times {( 1 - {P}_{2} )}^{n - 2 k - 1 + a} ; n \leq w , a \leq 2 k + 1$$

In one embodiment, the base station apparatus 110 determines a threshold value T as average of N₀ and N₁. In another embodiment, the pre-configuration may comprise multi-resource block, P_{FA} denotes a probability of false alarm, and P_{D} denotes a probability of detection. The base station apparatus 110 may determine that the P_{FA} is not equal to zero and that the P_{D} is not smaller than 0.5. Based on such determination, the base station apparatus 110 can further determine a threshold value T according to the P_{FA} and the P_{D}. The two probabilities can be formulated as follows:

P_{FA}=Σ_{i=T+1}^{Z}Cᵢ^{Z}×P_{NoInt}ⁱ×(1−P_{NoInt})^{Z-i}

P_{D}=Σ_{i=T+1}^{Z}Cᵢ^{Z}×P_{Int}ⁱ×(1−Pᵢₙₜ)^{Z-i}

The theoretical probability of the number of unsatisfied parity check equations under H₀ and H₁ can be computed as follows:

Pᵢ(H₀)=Cᵢ^{Z}×P_{NoInt}ⁱ(1−P_{NoInt})^{Z-i}

Pᵢ(H₀,H₁)=Cᵢ^{Z}×P_{Int}ⁱ(1−P_{Int})^{Z-i}

where Z denotes the sub-block size and i denotes the number of unsatisfied parity check equations.

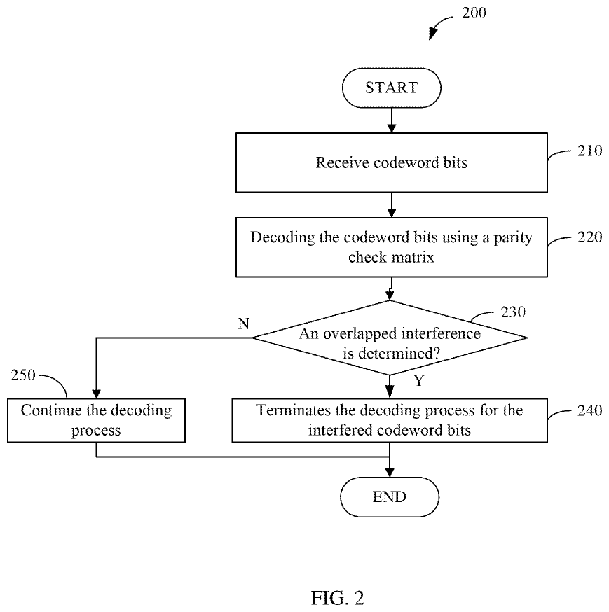

FIG. 2 illustrates a flowchart of a method 200 for processing interference in a shared channel, the method 200 being executed by the base station apparatus 110, according to an embodiment.

At block 210, the base station apparatus 110 receives codeword bits transmitted by the terminal apparatus 120 or 122. The codeword is encoded using an error code correction algorithm, such as LDPC.

At block 220, the base station apparatus 110 decodes the received codeword using a parity check matrix, wherein each row and each column in the parity check matrix is represented as a block, and each block representing a row (“row block”) comprises a plurality of parity check equations.

In one embodiment, before processing encoded codeword transmitted from each terminal apparatus 120/122, the base station apparatus 110 can analyze the theoretical number of unsatisfied parity-check equations which have and which have not interference. In one embodiment, the base station apparatus 110 can further predetermine a threshold value according to the theoretical number of initial unsatisfied parity-check equations with and without interference. In one embodiment, the base station apparatus 110 can compute the number of unsatisfied parity-check equations based on the channel state information, such as a signal-to-noise ratio, pre-configured resource block(s) for each terminal apparatus 120 and 122 respectively, an amplitude of the radio signal transmitted by each terminal apparatus 120 and 122 respectively, and the row block weight of the parity check matrix. In one embodiment, the base station apparatus 110 can predetermine the threshold value as the average value of the number of unsatisfied parity check equations without interference and the number of unsatisfied parity check equations with interference.

At block 230, the base station apparatus 110 determines whether there is an overlapped interference occurred on the received codeword. In one embodiment, the base station apparatus 110 firstly checks each block representing a column (“column block”) by selecting a row block from the plurality of row blocks with a minimum weight and an element in the parity check matrix positioned by the column block, the row block is non-zero-valued. The base station apparatus 110 then counts a number of unsatisfied parity check equations in the selected row block. Finally, the base station apparatus 110 determines whether interference occurs on the received codeword by comparing the number of the unsatisfied parity check equations with the predetermined threshold value. If the number of the unsatisfied parity check equations is larger than the predetermined threshold value, the base station apparatus 110 determines that there is interference and terminates decoding for the received codeword at block 240. Otherwise, if the number of the unsatisfied parity check equations is not larger than the predetermined threshold value, the base station apparatus 110 continuously decodes the received codeword at block 250. In other embodiment, the base stations apparatus 110 can also decode the codeword even if interfered-with by configuring a bit reliability of the interfered-with codeword as zero.

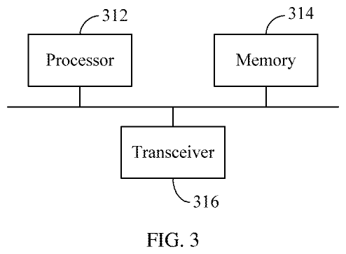

FIG. 3 illustrates a base station apparatus 110, according to an embodiment. The base station apparatus 110 comprises a processor 312, a memory 314, and a transceiver 316. The transceiver 316 comprises a transmitter configured to transmit data and a receiver configured to receive data. The processor 312 may process data and instructions. The processor may comprise an intelligent hardware device, e.g., a central processing unit (CPU), a microcontroller, and an ASIC. The memory 314 may store computer-readable, computer-executable instructions (e.g., software codes) that are configured to cause the processor 312 to perform various functions. The memory 314 may comprise volatile memory and non-volatile memory. The memory 314 may be removable, non-removable, or a combination thereof. Exemplary memories comprise solid-state memory, hard drives, optical-disc drives, and so on. The computer storage media stores information such as computer-readable instructions, data structures, program modules and other data. The computer-readable media can be any available media that can be accessed and which includes both volatile and non-volatile media, removable, and non-removable media. By way of example, and not limitation, the computer-readable media may comprise computer storage media and communication media. The computer storage media can comprise RAM, ROM, EEPROM, flash memory or other memory technology, CD-ROM, digital versatile disks (DVD) or other optical disk storage, magnetic cassettes, magnetic tape, magnetic disk storage or other magnetic storage devices.

In summary, the base station apparatus 110 improves interference problems between users on a shared channel. The method for processing signals or data which may have suffered interference provides a simple, effective way to distinguish the occurrence of interference.

The embodiments shown and described above are only examples. Many details are often found in the art such as the other features of a wireless communication system. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A method for processing multi-user transmissions applicable in a base station apparatus, the method comprising:
receiving a codeword transmitted by a terminal apparatus, wherein the codeword is encoded using an error correction algorithm;
decoding the received codeword using a parity check matrix;
determining whether an interference has occurred on the received codeword; and
terminating the decoding of the received codeword when the interference is determined.

2. The method of claim 1, wherein the error correction algorithm comprises a low-density parity check algorithm.

3. The method of claim 1, wherein the parity check matrix comprises a plurality of columns and a plurality of rows, each column of the plurality of columns defines a column block, each row of the plurality of rows defines a row block, and the row block of each of the plurality of rows comprises a plurality of parity check equations.

4. The method of claim 3, wherein the method of determining whether an interference has occurred on the received codeword comprises:
checking the column block of each of the plurality of columns by selecting a row block from the plurality of rows with a minimum weight and an element in the parity check matrix positioned by the checked column block and the selected row block is non-zero-valued;
counting a number of unsatisfied parity check equations from the plurality check equations of the selected row block;
comparing the number with a predetermined threshold value, and
determining an interference has occurred on the received codeword if the number is larger than the predetermined threshold value.

5. The method of claim 4, wherein the predetermined threshold value is computed based on a theoretical number of unsatisfied parity check equations without interference and a theoretical number of unsatisfied parity check equations with an interference.

6. A base station apparatus, comprising:
a processor; and
a memory for storing at least one computer program, wherein the computer program comprises instructions which are executed by the processor, and performs the following steps:
receiving a codeword transmitted by a terminal apparatus, wherein the codeword is encoded using an error correction algorithm;
decoding the received codeword using a parity check matrix;
determining whether an interference has occurred on the received codeword; and
terminating the decoding of the received codeword when the interference is determined.

7. The base station apparatus of claim 6, wherein the error correction algorithm comprises a low-density parity check algorithm.

8. The base station apparatus of claim 6, wherein the parity check matrix comprises a plurality of columns and a plurality of rows, each column of the plurality of columns defines a column block, each row of the plurality of rows defines a row block, and the row block of each of the plurality of rows comprises a plurality of parity check equations.

9. The base station apparatus of claim 8, wherein the method of determining whether an interference has occurred on the received codeword comprises:
checking the column block of each of the plurality of columns by selecting a row block from the plurality of rows with a minimum weight and an element in the parity check matrix positioned by the checked column block and the selected row block is non-zero-valued;
counting a number of unsatisfied parity check equations from the plurality check equation of the selected row block;
comparing the number with a predetermined threshold value, and
determining an interference has occurred on the received codeword if the number is larger than the predetermined threshold value.

10. The base station apparatus of claim 9, wherein the predetermined threshold value is computed based on a theoretical number of unsatisfied parity check equations without interference and a theoretical number of unsatisfied parity check equations with an interference.
